(19) United States
(12) Patent Application Publication
(10) Pub. No.: US 2025/0379458 A1
(43) Pub. Date: Dec. 11, 2025

(54) SEMICONDUCTOR DEVICE

(71) Applicant: FUJI ELECTRIC CO., LTD., Kawasaki-shi (JP)

(72) Inventor: Eiji KUROSAWA, Matsumoto-city (JP)

(73) Assignee: FUJI ELECTRIC CO., LTD., Kawasaki-shi (JP)

(21) Appl. No.: 19/190,372

(22) Filed: Apr. 25, 2025

(30) Foreign Application Priority Data
Jun. 11, 2024 (JP) 2024-094536

(51) Int. Cl. H02J 7/00; H03K 17/0812

(52) U.S. Cl. CPC H02J 7/00304; H02J 7/007; H03K 17/08122; H03K 17/08128

(57) ABSTRACT

A semiconductor device, including: a lower phase switching element connected in series with an upper phase switching element; a lower phase power supply which outputs a lower phase side driving voltage; a lower phase drive control circuit which receives the lower phase side driving voltage and drives and controls the lower phase switching element; a bootstrap circuit which receives a charging current from the lower phase power supply, responsive to the lower phase switching element being turned on, and generates a charging voltage therefrom; and an upper phase drive control circuit which receives the charging voltage as an upper phase side driving voltage, which includes a charging current limiting circuit for limiting the charging current flowing from the lower phase power supply to the bootstrap circuit according to a voltage level of the charging voltage, and which drives and controls the upper phase switching element.

### CROSS-REFERENCE TO RELATED APPLICATION

This application is based upon and claims the benefit of priority of the prior Japanese Patent Application No. 2024-094536, filed on Jun. 11, 2024, the entire contents of which are incorporated herein by reference.

### BACKGROUND OF THE INVENTION

### 1. Field of the Invention

The embodiment discussed herein relates to a semiconductor device.

### 2. Background of the Related Art

With semiconductor devices including an intelligent power module (IPM) with a built-in switching element which is a power semiconductor element, a bootstrap circuit is used for a driving voltage for driving a gate of an upper phase side switching element.

For example, a power converter including a charge and discharge resistor which suppresses an inrush current at the time of beginning a precharge of a smoothing capacitor and which discharges electric charges at the time of beginning a discharge is proposed as a related art (see, for example, Japanese Laid-open Patent Publication No. 2015-107045). Furthermore, a power control device which limits a current for preventing an inrush current by on-state resistance of a semiconductor switching element which is turned on for a predetermined period just after power application is proposed (see, for example, Japanese Laid-open Patent Publication No. 2009-044914).

### SUMMARY OF THE INVENTION

According to an aspect, there is provided a semiconductor device including an upper phase switching element; a lower phase switching element connected in series with the upper phase switching element; a lower phase power supply which outputs a lower phase side driving voltage; a lower phase drive control circuit which receives the lower phase side driving voltage, and drives and controls the lower phase switching element; a bootstrap circuit which receives a charging current from the lower phase power supply, responsive to the lower phase switching element being turned on by the lower phase drive control circuit, and generates a charging voltage therefrom; and an upper phase drive control circuit which receives the charging voltage as an upper phase side driving voltage, which includes a charging current limiting circuit for limiting the charging current flowing from the lower phase power supply to the bootstrap circuit according to a voltage level of the charging voltage, and which drives and controls the upper phase switching element.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a view for describing an example of a semiconductor device;

FIG. 2 illustrates an example of the entire structure of a semiconductor device taken as a reference example;

FIG. 3 is a view for describing the operation of a bootstrap circuit at initial charging time;

FIG. 4 illustrates an example of the waveform of a charging current at initial charging time;

FIG. 5 illustrates an example of the waveform of a charging voltage at initial charging time;

FIG. 6 illustrates a state obtained when the direction of a load current flowing at PWM operation time is negative;

FIG. 7 illustrates a state obtained when the direction of a load current flowing at PWM operation time is positive;

FIG. 8 is a view for describing fluctuations in upper phase side driving voltage at PWM operation time;

FIG. 9 illustrates an example of the entire structure of a semiconductor device according to an embodiment;

FIG. 10 illustrates an example of the structure of LVICs and bootstrap circuits on the upper phase side;

FIG. 11 illustrates an example of the operation of a charging current limiting circuit at initial charging beginning time;

FIG. 12 illustrates an example of the operation of the charging current limiting circuit performed when a charging voltage at initial charging time becomes higher than or equal to a predetermined level;

FIG. 13 illustrates an example of the waveform of a charging current at initial charging time;

FIG. 14 illustrates an example of the waveform of a charging voltage at initial charging time;

FIG. 15 is a view for describing fluctuations in upper phase side driving voltage at PWM operation time;

FIG. 16 illustrates a modification of the structure of the semiconductor device according to the embodiment;

FIG. 17 illustrates an example of the operation of a charging current limiting circuit at initial charging beginning time; and

FIG. 18 illustrates an example of the operation of the charging current limiting circuit performed when a charging voltage at initial charging time becomes higher than or equal to a predetermined level.

### DETAILED DESCRIPTION OF THE INVENTION

An embodiment will now be described by reference to the accompanying drawings. Components in the specification and drawings which have substantially the same structure are marked with the same numeral. By doing so, duplicate description may be omitted.

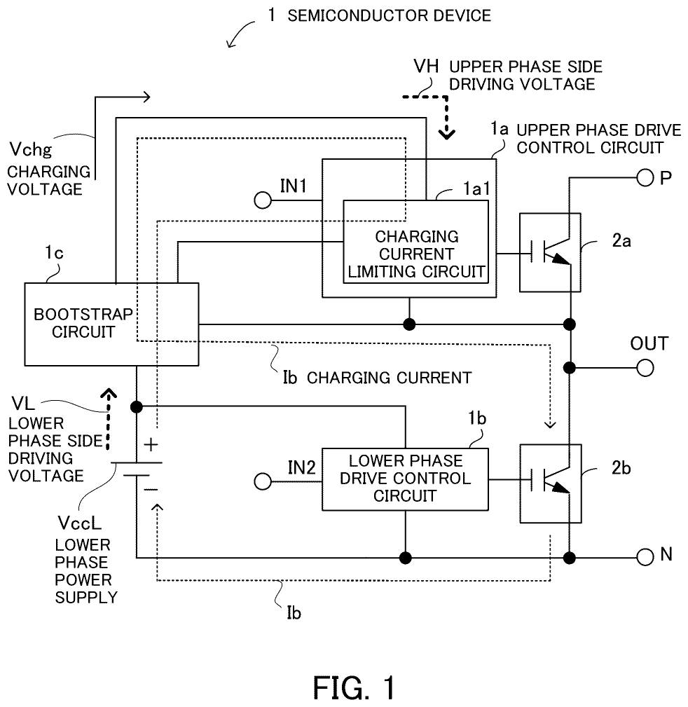

FIG. 1 is a view for describing an example of a semiconductor device. A semiconductor device 1 includes an upper phase switching element 2a, a lower phase switching element 2b, an upper phase drive control circuit 1a, a lower phase drive control circuit 1b, a bootstrap circuit 1c, and a lower phase power supply VccL. Furthermore, the upper phase drive control circuit 1a includes a charging current limiting circuit 1a1.

The upper phase switching element 2a and the lower phase switching element 2b are connected in series. A high potential main terminal of the upper phase switching element 2a is connected to a positive electrode terminal P. A low potential main terminal of the upper phase switching element 2a is connected to an output terminal OUT, a reference potential end of the upper phase drive control circuit 1a, a reference potential end of the bootstrap circuit 1c, and a high potential main terminal of the lower phase switching element 2b. A low potential main terminal of the lower phase switching element 2b is connected to a negative electrode terminal N, a reference potential end of the lower phase drive control circuit 1b, and a negative electrode end of the lower phase power supply VccL.

The lower phase power supply VccL outputs a lower phase side driving voltage VL. The lower phase drive control circuit 1b receives the lower phase side driving voltage VL and drives and controls the lower phase switching element 2b on the basis of a switching drive signal input via a lower phase input terminal IN2.

Furthermore, when the lower phase switching element 2b turns on as a result of driving and controlling by the lower phase drive control circuit 1b, a charging current Ib flows from a positive electrode end of the lower phase power supply VccL, through the bootstrap circuit 1c, the charging current limiting circuit 1a1, the bootstrap circuit 1c, the high potential main terminal of the lower phase switching element 2b, and the low potential main terminal of the lower phase switching element 2b, to the negative electrode end of the lower phase power supply VccL.

The bootstrap circuit 1c generates a charging voltage Vchg from electric charges stored on the basis of the charging current Ib flowing from the lower phase power supply VccL. The charging current limiting circuit 1a1 limits the charging current Ib flowing from the lower phase power supply VccL to the bootstrap circuit 1c according to a voltage level of the charging voltage Vchg.

The upper phase drive control circuit 1a receives, as an upper phase side driving voltage VH, the charging voltage Vchg output from the bootstrap circuit 1c by discharging and drives and controls the upper phase switching element 2a.

With the semiconductor device 1, as stated above, the charging current Ib flowing from the lower phase power supply VccL to the bootstrap circuit 1c is limited according to a voltage level of the charging voltage Vchg. This suppresses the generation of a large charging current (inrush current) at initial charging time. Furthermore, initial charging time is shortened and fluctuations in upper phase side driving voltage are suppressed.

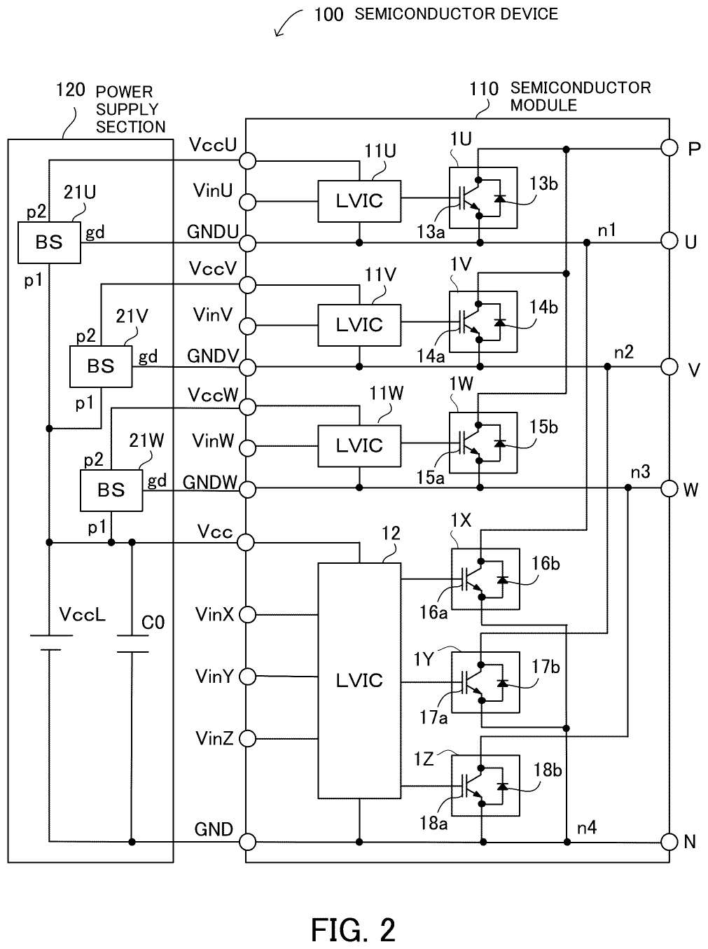

A semiconductor device taken as a reference example will now be described with reference to FIGS. 2 through 8. FIG. 2 illustrates an example of the entire structure of a semiconductor device taken as a reference example. A semiconductor device 100 includes a semiconductor module 110 and a power supply section 120.

The semiconductor module 110 includes low voltage ICS (LVICs) 11U, 11V, 11W, and 12 and semiconductor chips 1U, 1V, 1W, 1X, 1Y, and 1Z and has the function of an IPM.

The LVIC 11U and the semiconductor chip 1U are located on a U phase on the upper phase side (high side). The LVIC 11V and the semiconductor chip 1V are located on a V phase on the upper phase side. The LVIC 11W and the semiconductor chip 1W are located on a W phase on the upper phase side.

The LVIC 12 is located on the lower phase side (low side). The semiconductor chip 1X is located on an X phase on the lower phase side. The semiconductor chip 1Y is located on a Y phase on the lower phase side. The semiconductor chip 1Z is located on a Z phase on the lower phase side.

With the semiconductor device 100, as stated above, the LVICs 11U, 11V, and 11W are located as gate drivers for driving the upper phase semiconductor chips 1U, 1V, and 1W, respectively, and the LVIC 12 is located as a gate driver for driving the lower phase semiconductor chips 1X, 1Y, and 1Z.

The semiconductor chip 1U includes a U-phase switching element 13a and a free wheel diode (FWD) 13b connected in inverse parallel therewith. The semiconductor chip 1V includes a V-phase switching element 14a and an FWD 14b connected in inverse parallel therewith. The semiconductor chip 1W includes a W-phase switching element 15a and an FWD 15b connected in inverse parallel therewith.

Furthermore, the semiconductor chip 1X includes an X-phase switching element 16a and an FWD 16b connected in inverse parallel therewith. The semiconductor chip 1Y includes a Y-phase switching element 17a and an FWD 17b connected in inverse parallel therewith. The semiconductor chip 1Z includes a Z-phase switching element 18a and an FWD 18b connected in inverse parallel therewith.

Each of the U-phase switching element 13a, the V-phase switching element 14a, the W-phase switching element 15a, the X-phase switching element 16a, the Y-phase switching element 17a, and the Z-phase switching element 18a is a voltage-driven switching element and is an insulated gate bipolar transistor (IGBT). Alternatively, it may be that each of the U-phase switching element 13a, the V-phase switching element 14a, the W-phase switching element 15a, the X-phase switching element 16a, the Y-phase switching element 17a, and the Z-phase switching element 18a is not an IGBT but a power metal-oxide-semiconductor field-effect transistor (MOSFET).

In addition, each of the FWDs 13b, 14b, 15b, 16b, 17b, and 18b is a free wheel diode which circulates a load current. If each of the U-phase switching element 13a, the V-phase switching element 14a, the W-phase switching element 15a, the X-phase switching element 16a, the Y-phase switching element 17a, and the Z-phase switching element 18a is a power MOSFET, then an FWD may be realized by a parasitic diode.

The semiconductor module 110 has, as upper phase side terminals, a terminal VccU (U-phase driving power supply terminal), a terminal VccV (V-phase driving power supply terminal), a terminal VccW (W-phase driving power supply terminal), a terminal VinU (U-phase input terminal), a terminal VinV (V-phase input terminal), a terminal VinW (W-phase input terminal), a terminal GNDU (U-phase GND terminal), a terminal GNDV (V-phase GND terminal), and a terminal GNDW (W-phase GND terminal).

Furthermore, the semiconductor module 110 has, as lower phase side terminals, a terminal Vcc, a terminal VinX (X-phase input terminal), a terminal VinY (Y-phase input terminal), a terminal VinZ (Z-phase input terminal), and a terminal GND. Moreover, the semiconductor module 110 has a positive electrode terminal P, a negative electrode terminal N, an output terminal U, an output terminal V, and an output terminal W.

Collectors of the U-phase switching element 13a, the V-phase switching element 14a, and the W-phase switching element 15a are connected to the positive electrode terminal P. A node n1 to which an emitter of the U-phase switching element 13a and a collector of the X-phase switching element 16a are connected is connected to the terminal GNDU, a reference potential end of the LVIC 11U, and the output terminal U.

A node n2 to which an emitter of the V-phase switching element 14a and a collector of the Y-phase switching element 17a are connected is connected to the terminal GNDV, a reference potential end of the LVIC 11V, and the output terminal V.

A node n3 to which an emitter of the W-phase switching element 15a and a collector of the Z-phase switching element 18a are connected is connected to the terminal GNDW, a reference potential end of the LVIC 11W, and the output terminal W.

A node n4 to which an emitter of the X-phase switching element 16a, an emitter of the Y-phase switching element 17a, and an emitter of the Z-phase switching element 18a are connected is connected to the terminal GND, a reference potential end of the LVIC 12, and the negative electrode terminal N.

On the other hand, the power supply section 120 includes a lower phase power supply VccL, bootstrap (BS) circuits 21U, 21V, and 21W, and a smoothing capacitor C0. The bootstrap circuit 21U is located on the U phase on the upper phase side. The bootstrap circuit 21V is located on the V phase on the upper phase side. The bootstrap circuit 21W is located on the W phase on the upper phase side. The lower phase power supply VccL and the smoothing capacitor C0 are located on the lower phase side.

A positive electrode end of the lower phase power supply VccL is connected to the terminal Vcc, one end of the smoothing capacitor C0, and first terminals p1 of the bootstrap circuits 210, 21V, and 21W. A charging current is input to each first terminal p1 at initial charging time. A negative electrode end of the lower phase power supply VccL is connected to the other end of the smoothing capacitor C0 and the terminal GND.

A second terminal p2 of the bootstrap circuit 21U is connected to the terminal VccU. A second terminal p2 of the bootstrap circuit 21V is connected to the terminal VccV. A second terminal p2 of the bootstrap circuit 21W is connected to the terminal VccW. A charging current is input to each second terminal p2 and a charging voltage is discharged from each second terminal p2.

A reference potential end gd of the bootstrap circuit 21U is connected to the terminal GNDU. A reference potential end gd of the bootstrap circuit 21V is connected to the terminal GNDV. A reference potential end gd of the bootstrap circuit 21W is connected to the terminal GNDW.

The bootstrap circuit 21U generates a driving voltage (upper phase side driving voltage) for driving a gate of the U-phase switching element 13a on the basis of a power supply voltage (lower phase side driving voltage) output from the lower phase power supply VccL, and supplies the driving voltage to the LVIC 11U via the terminal VccU. The LVIC 11U receives via the terminal VinU a U-phase driving signal transmitted from a control unit (not illustrated), such as a microcomputer, and drives (switching-drives, that is to say, turns on or turns off) the U-phase switching element 13a on the basis of the U-phase driving signal.

Furthermore, the bootstrap circuit 21V generates a driving voltage for driving a gate of the V-phase switching element 14a on the basis of a power supply voltage output from the lower phase power supply VccL, and supplies the driving voltage to the LVIC 11V via the terminal VccV. The LVIC 11V receives via the terminal VinV a V-phase driving signal transmitted from the control unit and drives the V-phase switching element 14a on the basis of the V-phase driving signal.

In addition, the bootstrap circuit 21W generates a driving voltage for driving a gate of the W-phase switching element 15a on the basis of a power supply voltage output from the lower phase power supply VccL, and supplies the driving voltage to the LVIC 11W via the terminal VccW. The LVIC 11W receives via the terminal VinW a W-phase driving signal transmitted from the control unit and drives the W-phase switching element 15a on the basis of the W-phase driving signal.

On the other hand, the LVIC 12 uses a power supply voltage of the lower phase power supply VccL as a driving voltage for driving a gate of the X-phase switching element 16a, a driving voltage for driving a gate of the Y-phase switching element 17a, and a driving voltage for driving a gate of the Z-phase switching element 18a. Furthermore, the LVIC 12 receives via the terminal VinX an X-phase driving signal transmitted from the control unit and drives the X-phase switching element 16a on the basis of the X-phase driving signal.

Similarly, the LVIC 12 receives via the terminal VinY a Y-phase driving signal transmitted from the control unit and drives the Y-phase switching element 17a on the basis of the Y-phase driving signal. In addition, the LVIC 12 receives via the terminal VinZ a Z-phase driving signal transmitted from the control unit and drives the Z-phase switching element 18a on the basis of the Z-phase driving signal.

With the semiconductor device 100, the bootstrap circuits 21U, 21V, and 21W are applied in this way to an upper phase side power supply. Each of the bootstrap circuits 21U, 21V, and 21W is made up of a diode, a capacitor, and a limiting resistor (internal circuit structure will be described later). As a result, the size of the parts included in the semiconductor device 100 is reduced, compared with a semiconductor device in which a power supply is located for each of the U phase, the V phase, and the W phase.

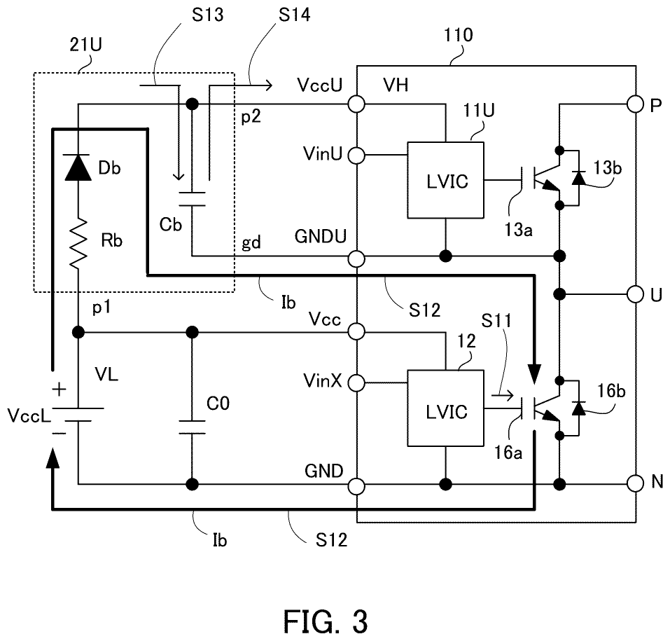

The operation of a bootstrap circuit at initial charging time of the semiconductor device 100 will now be described with reference to FIGS. 3 through 5. Because the circuit structure and operation of the bootstrap circuits for the U phase, the V phase, and the W phase are the same, the following description will be given for the U phase.

FIG. 3 is a view for describing the operation of a bootstrap circuit at initial charging time. The bootstrap circuit 21U includes a diode Db, a capacitor Cb, and a limiting resistor Rb.

One end of the limiting resistor Rb is connected to the positive electrode end of the lower phase power supply VccL, the one end of the smoothing capacitor C0, and the terminal Vcc. The other end of the limiting resistor Rb is connected to an anode of the diode Db. A cathode of the diode Db is connected to one end of the capacitor Cb and the terminal VccU. The other end of the capacitor Cb is connected to the terminal GNDU. The bootstrap circuit 21U having this structure performs the following operation at initial charging time.

(Step S11) The LVIC 12 turns on the X-phase switching element 16a on the basis of an X-phase driving signal input via the terminal VinX.

(Step S12) When the X-phase switching element 16a turns on, the other end of the capacitor Cb is electrically conducted with the negative electrode end of the lower phase power supply VccL via the terminal GNDU and the terminal GND. As a result, a charging current Ib flows from the positive electrode end of the lower phase power supply VccL, through the limiting resistor Rb, the anode of the diode Db, the cathode of the diode Db, the collector of the X-phase switching element 16a, and the emitter of the X-phase switching element 16a, to the negative electrode end of the lower phase power supply VccL.

(Step S13) Because the charging current Ib flows, electric charges are stored in the capacitor Cb.

(Step S14) The electric charges stored in the capacitor Cb are discharged. A charging voltage discharged at this time is applied to the LVIC 11U via the terminal VccU and an upper phase side driving voltage VH established is used as a gate driving voltage of the LVIC 11U. A lower phase side driving voltage VL output from the lower phase power supply VccL is supplied as a gate driving voltage of the LVIC 12.

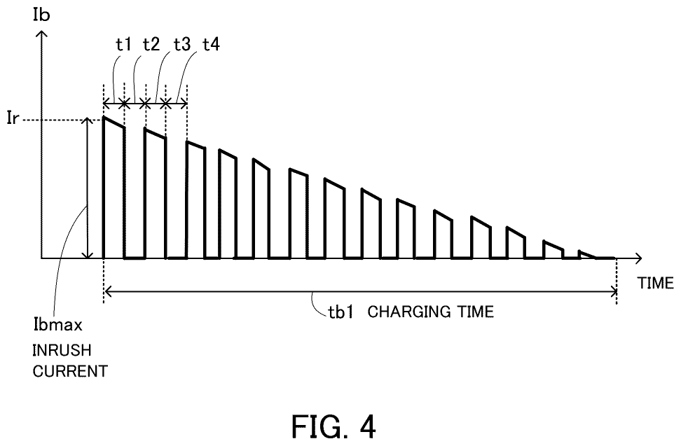

FIG. 4 illustrates an example of the waveform of a charging current at initial charging time. In FIG. 4, a vertical axis indicates the charging current Ib and a horizontal axis indicates time.

(Interval t1) When the LVIC 12 receives via the terminal VinX an X-phase driving signal which gives instructions to turn on the X-phase switching element 16a, the LVIC 12 turns on the X-phase switching element 16a.

At this time, as stated above, the charging current Ib flows to the capacitor Cb. However, the capacitor Cb is in a state before being charged, that is to say, in a state in which electric charges are not stored. Accordingly, a large current (inrush current Ibmax) flows to the capacitor Cb. However, the bootstrap circuit 21U includes the limiting resistor Rb for suppressing an inrush current. As a result, a peak value of the inrush current Ibmax is suppressed so as not to exceed a rated current value Ir.

(Interval t2) When the LVIC 12 receives via the terminal VinX an X-phase driving signal which gives instructions to turn off the X-phase switching element 16a, the LVIC 12 turns off the X-phase switching element 16a. Because at this time the other end of the capacitor Cb is not electrically conducted with the negative electrode end of the lower phase power supply VccL, the charging current Ib does not flow.

(Interval t3) When the LVIC 12 receives via the terminal VinX an X-phase driving signal which gives instructions to turn on the X-phase switching element 16a, the LVIC 12 turns on the X-phase switching element 16a. In this case, the charging current Ib flows to the capacitor Cb. However, electric charges are stored in the capacitor Cb during interval t1. Accordingly, a peak value of the charging current Ib flowing to the capacitor Cb during interval t3 is smaller than a peak value of the charging current Ib flowing to the capacitor Cb during interval t1.

(Interval t4) When the LVIC 12 receives via the terminal VinX an X-phase driving signal which gives instructions to turn off the X-phase switching element 16a, the LVIC 12 turns off the X-phase switching element 16a. Because at this time the other end of the capacitor Cb is not electrically conducted with the negative electrode end of the lower phase power supply VccL, the charging current Ib does not flow.

The same operation is repeated until electric charges are fully stored in the capacitor Cb. When charging time tb1 is taken to fully store electric charges in the capacitor Cb, initial charging ends and there is a shift to an operation state.

With the initial charging operation, as stated above, switching of the X-phase switching element 16a (lower phase IGBT) is performed, that is to say, the X-phase switching element 16a is turned on and off and electric charges are stored in the capacitor Cb in the bootstrap circuit 21U (capacitor in an upper phase bootstrap circuit).

When electric charges are not stored in the capacitor Cb, the charging current Ib corresponding to the inrush current Ibmax having a maximum current value flows to the capacitor Cb. As the amount of electric charges stored in the capacitor Cb increases, a current value of the charging current Ib decreases.

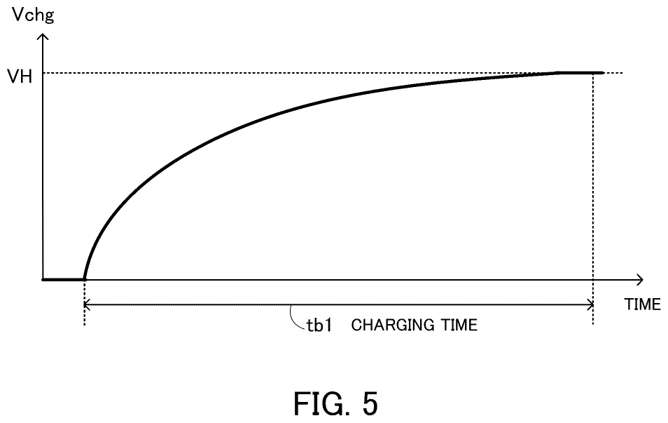

FIG. 5 illustrates an example of the waveform of a charging voltage at initial charging time. In FIG. 5, a vertical axis indicates a charging voltage Vchg and a horizontal axis indicates time. The charging current Ib flows to the capacitor Cb and electric charges are gradually stored in the capacitor Cb. As a result, the charging voltage Vchg discharged from the capacitor Cb rises.

The charging time tb1 is taken from the time when storing electric charges in the capacitor Cb is begun to the time when storing electric charges in the capacitor Cb is completed. When storing electric charges in the capacitor Cb is completed, the charging voltage Vchg reaches a charging voltage (upper phase side driving voltage VH) having a constant voltage value. As a result, an initial charging state ends and there is a shift to a device operation state.

As the charging current Ib increases, the speed at which electric charges are stored in the capacitor Cb increases. As a result, the charging time tb1 becomes shorter. As the charging current Ib decreases, the speed at which electric charges are stored in the capacitor Cb decreases. As a result, the charging time tb1 becomes longer.

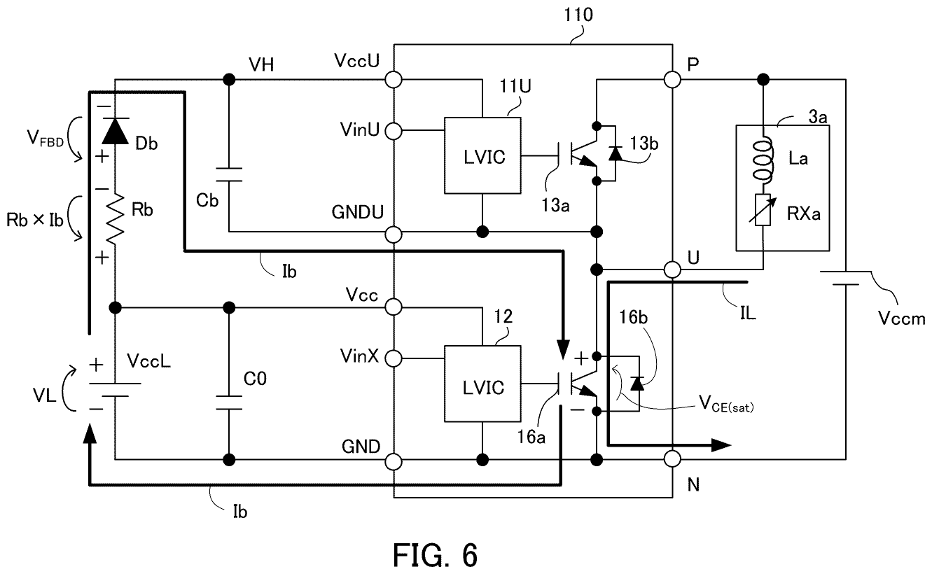

The operation of a bootstrap circuit at pulse width modulation (PWM) operation time will now be described with reference to FIGS. 6 through 8. When initial charging ends, the semiconductor device 100 shifts to an operation state and power control of a switching element by PWM is exercised.

FIG. 6 illustrates a state obtained when the direction of a load current flowing at PWM operation time is negative. A load 3a and a power source Vccm are connected to the semiconductor module 110. The load 3a is an inductive load, such as a motor, and includes an inductor La and a variable resistor RXa. One end of the inductor La is connected to the positive electrode terminal P and a positive electrode end of the power source Vccm. The other end of the inductor La is connected to one end of the variable resistor RXa. The other end of the variable resistor RXa is connected to the output terminal U. A negative electrode end of the power source Vccm is connected to the negative electrode terminal N.

The above circuit structure is adopted. When the X-phase switching element 16a turns on, the charging current Ib flows in the direction illustrated in FIG. 3. Furthermore, if the X-phase switching element 16a turns on and the direction of a load current IL flowing from the load 3a is negative, then the load current IL flows from the load 3a, through the output terminal U, the collector of the X-phase switching element 16a, and the emitter of the X-phase switching element 16a, to the negative electrode terminal N.

In an operation mode (hereinafter referred to as mode m1) in which the direction of the load current IL is negative, the upper phase side driving voltage VH applied to the terminal VccU is calculated by the following equation (1).

$$VH = VL - {V}_{FBD} - Rb \times Ib - {V}_{ce ( sat )} \qquad ( 1 )$$

In equation (1), VL is a voltage of the lower phase power supply VccL (lower phase side driving voltage), V_{FBD} is a forward voltage of the diode Db, Rb is a resistance value of the limiting resistor Rb, Ib is a current value of the charging current Ib, and V_{ce(sat)} is a collector-emitter saturation voltage obtained when the load current IL flows through the X-phase switching element 16a.

A direction from the negative electrode end to the positive electrode end of the lower phase power supply VccL is a positive value and the lower phase side driving voltage VL is positive. Therefore, if the charging current Ib flows in a direction indicated by an arrow in FIG. 6, then a voltage across the limiting resistor Rb (Rb×Ib) is a negative value with respect to the lower phase side driving voltage VL and a forward voltage V_{FBD} of the diode Db is a negative value with respect to the lower phase side driving voltage VL. Furthermore, in mode m1 the load current IL flows in a direction from the collector to the emitter of the X-phase switching element 16a. Accordingly, V_{ce(sat)} is a negative value with respect to the lower phase side driving voltage VL.

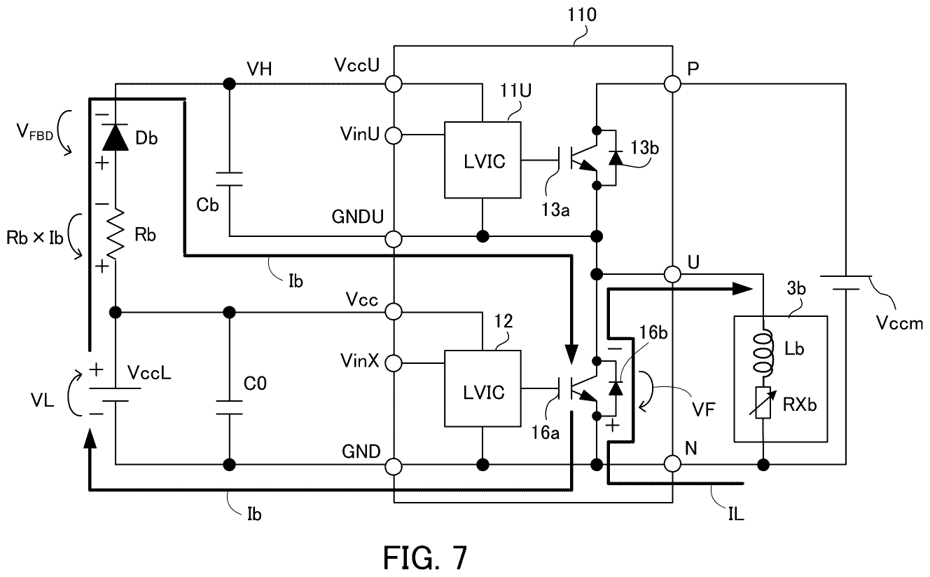

FIG. 7 illustrates a state obtained when the direction of a load current flowing at PWM operation time is positive. A load 3b and a power source Vccm are connected to the semiconductor module 110. The load 3b is an inductive load, such as a motor, and includes an inductor Lb and a variable resistor RXb. One end of the inductor Lb is connected to the output terminal U. The other end of the inductor Lb is connected to one end of the variable resistor RXb. The other end of the variable resistor RXb is connected to the negative electrode terminal N and a negative electrode end of the power source Vccm. A positive electrode end of the power source Vccm is connected to the positive electrode terminal P.

The above circuit structure is adopted. When the X-phase switching element 16a turns on, the charging current Ib flows in the direction illustrated in FIG. 3. Furthermore, if the X-phase switching element 16a turns on and the direction of a load current IL flowing from the load 3b is positive, then the load current IL flows from the load 3b, through the negative electrode terminal N, the anode of the FWD 16b, the cathode of the FWD 16b, and the output terminal U, to the load 3b.

In an operation mode (hereinafter referred to as mode m2) in which the direction of the load current IL is positive, the upper phase side driving voltage VH applied to the terminal VccU is calculated by the following equation (2).

$$VH = VL - {V}_{FBD} - Rb \times Ib + VF \qquad ( 2 )$$

In equation (2), VF is a forward voltage obtained when the load current IL is circulating through the FWD 16b. Furthermore, in mode m2 the load current IL flows in a direction from the anode to the cathode of the FWD 16b. Accordingly, VF is a positive value with respect to the lower phase side driving voltage VL.

If the lower phase side driving voltage VL of the lower phase power supply VccL is 15 V, then the upper phase side driving voltage VH in mode m1 is lower than 15 V (VH<15 V) from equation (1). Furthermore, if the lower phase side driving voltage VL is 15 V and (V_{FBD}+Rb×Ib)<VF, then the upper phase side driving voltage VH in mode m2 is higher than 15 V (VH>15 V) from equation (2).

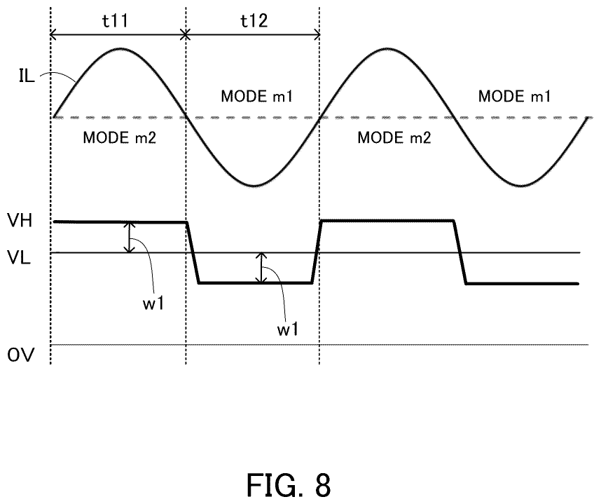

FIG. 8 is a view for describing fluctuations in upper phase side driving voltage at PWM operation time.

(Interval t11) PWM operation is performed in mode m2. The load current IL flows in a positive direction from the output terminal U to the load 3b. In this case, the upper phase side driving voltage VH is higher in a positive direction than the lower phase side driving voltage VL of the lower phase power supply VccL by a fluctuation width w1. Because the lower phase power supply VccL is a constant power supply, the lower phase side driving voltage VL is constant.

(Interval t12) PWM operation is performed in mode m1. A load current IL flows in a negative direction from the load 3a to the output terminal U. In this case, the upper phase side driving voltage VH is higher in a negative direction than the lower phase side driving voltage VL of the lower phase power supply VccL by the fluctuation width w1. After that, mode m1 and mode m2 are repeated in the same way.

The upper phase side driving voltage VH fluctuates in this way according to operation mode, that is to say, according to mode m1 and mode m2. Furthermore, it is known from equations (1) and (2) that the fluctuation width w1 of the upper phase side driving voltage VH depends greatly on a resistance value of the limiting resistor Rb. As a resistance value of the limiting resistor Rb increases, fluctuations in the upper phase side driving voltage VH become larger. As a resistance value of the limiting resistor Rb decreases, fluctuations in the upper phase side driving voltage VH become smaller.

As stated above, the bootstrap circuit 21U includes the limiting resistor Rb. A resistance value of the limiting resistor Rb is set so that a peak value of an inrush current at initial charging time does not exceed a rated value. However, a resistance value of the limiting resistor Rb is fixed. If a resistance value of the limiting resistor Rb is too large, then charging time at initial charging time becomes long and it takes time to start the device. Furthermore, if a resistance value of the limiting resistor Rb is too large, then fluctuations in the upper phase side driving voltage VH become large at PWM operation time and circuit operation becomes unstable.

On the other hand, if a resistance value of the limiting resistor Rb is made small to reduce charging time at initial charging time and decrease fluctuations in the upper phase side driving voltage VH, then there is a possibility that a peak value of an inrush current exceeds a rated value.

With the semiconductor device 100 taken as a reference example, as stated above, contrary characteristics are obtained according to fixed resistance values set to the limiting resistor Rb. The above problems arise in both of a case where a large resistance value is set to the limiting resistor Rb and a case where a small resistance value is set to the limiting resistor Rb.

The problems with the bootstrap circuit 21U located on the U phase on the upper phase side have been described. With the bootstrap circuit 21V located on the V phase on the upper phase side and the bootstrap circuit 21W located on the W phase on the upper phase side, however, the same problems arise.

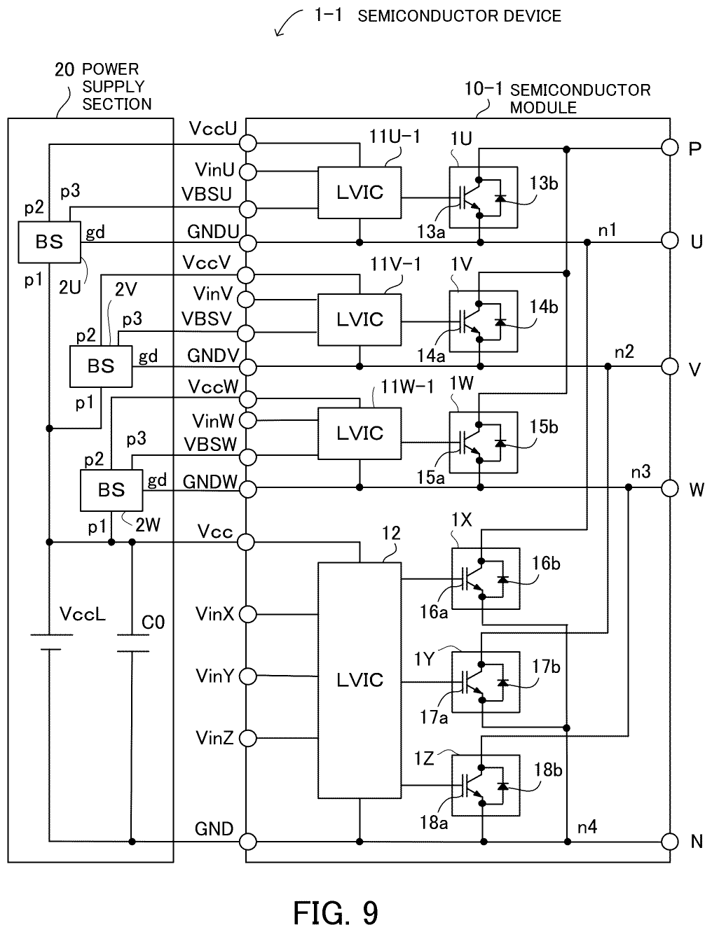

A semiconductor device according to an embodiment will now be described in detail. FIG. 9 illustrates an example of the entire structure of a semiconductor according to an embodiment. A semiconductor device 1-1 includes a semiconductor module 10-1 and a power supply section 20. The semiconductor module 10-1 includes LVICs 11U-1, 11V-1, 11W-1, and 12 and semiconductor chips 10, 1V, 1W, 1X, 1Y, and 1Z and has the function of an IPM.

Furthermore, in addition to the terminals described in FIG. 2, the semiconductor module 10-1 has, as upper phase side terminals, a terminal VBSU (U-phase bootstrap input terminal), a terminal VBSV (V-phase bootstrap input terminal), and a terminal VBSW (W-phase bootstrap input terminal).

On the other hand, the power supply section 20 includes a lower phase power supply VccL, bootstrap circuits 2U, 2V, and 2W, and a smoothing capacitor C0. The bootstrap circuit 2U is located on the U phase on the upper phase side. The bootstrap circuit 2V is located on the V phase on the upper phase side. The bootstrap circuit 2W is located on the W phase on the upper phase side. The lower phase power supply VccL and the smoothing capacitor C0 are located on the lower phase side.

A third terminal p3 of the bootstrap circuit 2U is connected to the terminal VBSU, a third terminal p3 of the bootstrap circuit 2V is connected to the terminal VBSV, and a third terminal p3 of the bootstrap circuit 2W is connected to the terminal VBSW. Because the other connection methods are the same with FIG. 2, their descriptions will be omitted.

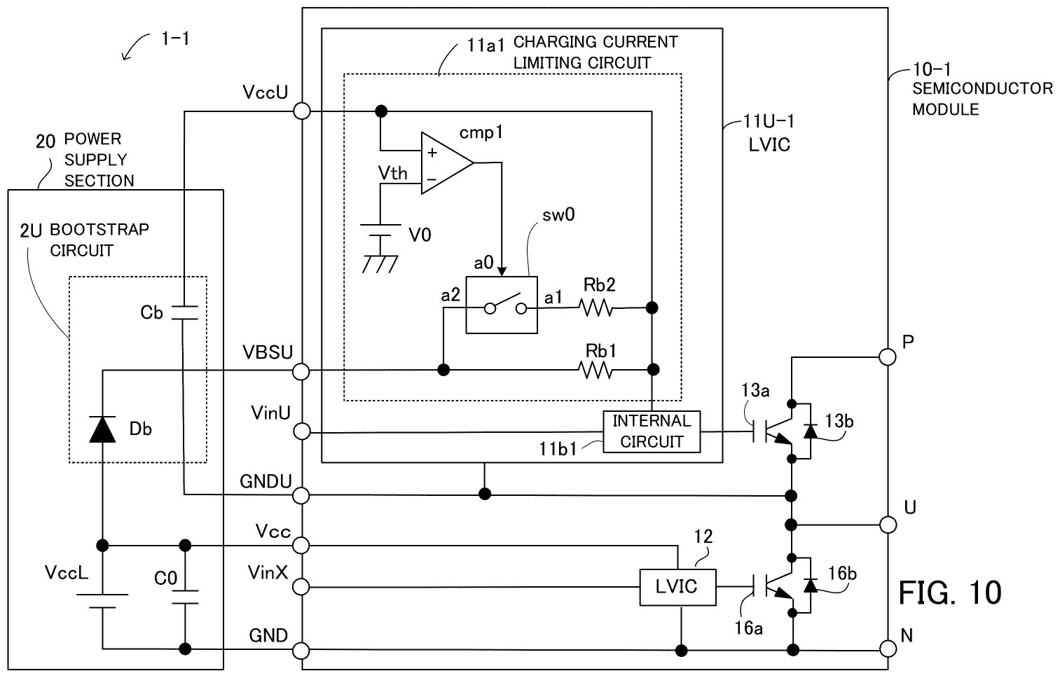

FIG. 10 illustrates an example of the structure of LVICs and bootstrap circuits on the upper phase side. The same circuit structure is adopted and the same operation is performed on the U phase, the V phase, and the W phase. Accordingly, the LVIC 11U-1 and the bootstrap circuit 2U located on the U phase side will now be described.

The LVIC 11U-1 in the semiconductor module 10-1 includes a charging current limiting circuit 11a1 and an internal circuit 11b1. The charging current limiting circuit 11a1 includes a comparator cmp1, a threshold voltage output source V0, a switch sw0, a limiting resistor Rb1 (first limiting resistor), and a limiting resistor Rb2 (second limiting resistor). The internal circuit 11b1 includes a gate driver which drives a U-phase switching element 13a by a driving signal received via a terminal VinU and the like.

Furthermore, the bootstrap circuit 2U in the power supply section 20 includes a diode Db and a capacitor Cb. With the semiconductor device 1-1, the bootstrap circuit 2U does not include a limiting resistor and the limiting resistors Rb1 and Rb2 are located in the LVIC 11U-1.

The components of the charging current limiting circuit 11a1 are connected in the following way. A non-inverting input terminal (+) of the comparator cmp1 is connected to a terminal VccU, one end of the limiting resistor Rb1, one end of the limiting resistor Rb2, and a power supply voltage supply end of the internal circuit 11b1. An inverting input terminal (−) of the comparator cmp1 is connected to a positive electrode end of the threshold voltage output source V0. A negative electrode end of the threshold voltage output source V0 is connected to a terminal GND.

The other end of the limiting resistor Rb1 is connected to a signal output terminal a2 of the switch sw0 and the terminal VBSU. The other end of the limiting resistor Rb2 is connected to a signal input terminal a1 of the switch sw0. An output terminal of the comparator cmp1 is connected to a switching control terminal a0 of the switch sw0. The components of the power supply section 20 are connected in the following way. An anode of the diode Db is connected to a positive electrode end of the lower phase power supply VccL, one end of the smoothing capacitor C0, and a terminal Vcc. A cathode of the diode Db is connected to the terminal VBSU. One end of the capacitor Cb is connected to the terminal VccU and the other end of the capacitor Cb is connected to a terminal GNDU. A negative electrode end of the lower phase power supply VccL is connected to the other end of the smoothing capacitor C0 and the terminal GND.

It is assumed that an inrush current Ibmax flows through the limiting resistor Rb1 at initial charging beginning time. The limiting resistor Rb1 has a resistance value which makes it possible to perform current limitation so that a peak value of the inrush current Ibmax does not exceed a rated current value Ir (resistance value of the limiting resistor Rb1 may be equal to that of the limiting resistor Rb illustrated in FIG. 3). Moreover, it is assumed that the inrush current Ibmax flows through a parallel combined resistor of the limiting resistors Rb1 and Rb2. The limiting resistor Rb2 has a resistance value which makes it possible to perform current limitation so that a peak value of the inrush current Ibmax does not exceed the rated current value Ir.

For example, it is assumed that if a resistance value of the parallel combined resistor of the limiting resistors Rb1 and Rb2 is 50Ω, it is possible to perform current limitation so that a peak value of the inrush current Ibmax does not exceed the rated current value Ir. In this case, if a resistance value of the limiting resistor Rb1 is set to 100Ω, it is possible to perform current limitation so that a peak value of the inrush current Ibmax does not exceed the rated current value Ir. Furthermore, if a resistance value of the limiting resistor Rb2 is set to 200Ω, then a resistance value of the parallel combined resistor of the limiting resistors Rb1 and Rb2 is 67Ω (>50Ω). As a result, even if the inrush current Ibmax flows through the parallel combined resistor of the limiting resistors Rb1 and Rb2, it is possible to perform current limitation so that a peak value of the inrush current Ibmax does not exceed the rated current value Ir. Accordingly, a resistance value of the limiting resistor Rb2 may be set to 200Ω. On the other hand, if a resistance value of the limiting resistor Rb2 is set to 80Ω, then a resistance value of the parallel combined resistor of the limiting resistors Rb1 and Rb2 is 44Ω and is lower than 50Ω. Accordingly, it is improper to set a resistance value of the limiting resistor Rb2 to 80Ω. A resistance value of the parallel combined resistor of the limiting resistors Rb1 and Rb2 is lower than a resistance value of the limiting resistor Rb1.

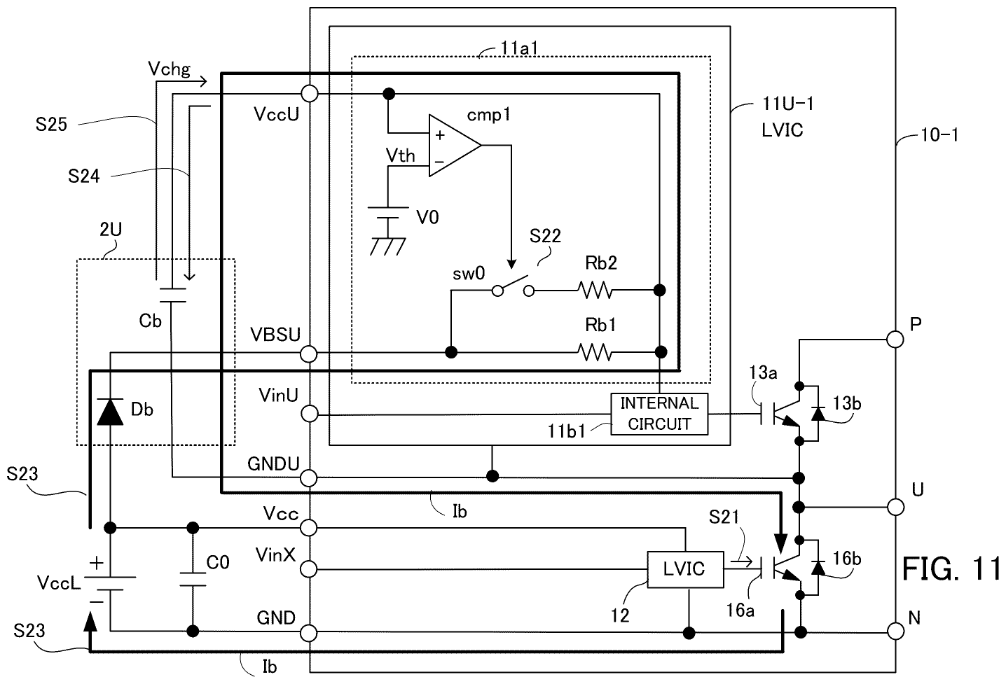

FIG. 11 illustrates an example of the operation of a charging current limiting circuit at initial charging beginning time.

(Step S21) On the basis of an X-phase driving signal input via a terminal VinX, the LVIC 12 turns on an X-phase switching element 16a.

(Step S22) A voltage at a predetermined level is not applied to the terminal VccU at initial charging beginning time. A voltage level at the terminal VccU is lower than a threshold voltage Vth output from the threshold voltage output source V0. A voltage at the predetermined level may be equal to the threshold voltage Vth.

At this time, an L-level signal is output from the comparator cmp1. The switch sw0 receives the L-level signal and turns off. In this case, the terminal VccU is connected to the terminal VBSU via the limiting resistor Rb1.

(Step S23) The one end of the capacitor Cb is electrically conducted with the positive electrode end of the lower phase power supply VccL via the terminal VccU, the limiting resistor Rb1, and the diode Db. Furthermore, when the X-phase switching element 16a turns on, the other end of the capacitor Cb is electrically conducted with the negative electrode end of the lower phase power supply VccL via the terminal GNDU and the terminal GND. As a result, a charging current Ib flows.

At this time, the charging current Ib flows from the positive electrode end of the lower phase power supply VccL, through the anode of the diode Db, the cathode of the diode Db, the limiting resistor Rb1, the terminal VccU, the capacitor Cb, a collector of the X-phase switching element 16a, and an emitter of the X-phase switching element 16a, to the negative electrode end of the lower phase power supply VccL.

(Step S24) Because the charging current Ib flows, electric charges are stored in the capacitor Cb.

(Step S25) Electric charges stored in the capacitor Cb are discharged and a charging voltage Vchg is output from the capacitor Cb by discharging to the terminal VccU.

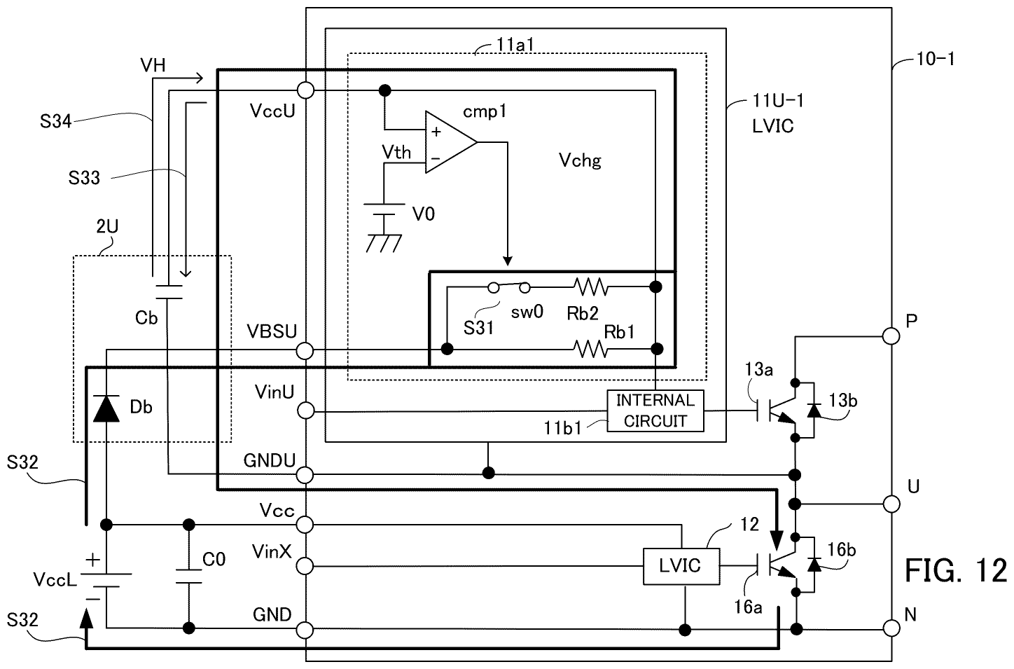

FIG. 12 illustrates an example of the operation of the charging current limiting circuit performed when a charging voltage at initial charging time becomes higher than or equal to the predetermined level.

(Step S31) Initial charging is begun. After the elapse of predetermined time, a voltage level of the charging voltage Vchg rises. A voltage at the predetermined level is applied to the terminal VccU and is higher than or equal to the threshold voltage Vth. At this time, an H-level signal is output from the comparator cmp1. The switch sw0 receives the H-level signal and turns on. In this case, the terminal VccU is connected to the terminal VBSU via the parallel combined resistor of the limiting resistors Rb1 and Rb2.

(Step S32) The charging current Ib flows from the positive electrode end of the lower phase power supply VccL, through the anode of the diode Db, to the cathode of the diode Db. Furthermore, because the switch sw0 turns on, the charging current Ib flows through the parallel combined resistor of the limiting resistors Rb1 and Rb2. In addition, the charging current Ib flows from the terminal VccU, through the capacitor Cb, the collector of the X-phase switching element 16a, and the emitter of the X-phase switching element 16a, to the negative electrode end of the lower phase power supply VccL.

(Step S33) Electric charges are stored in the capacitor Cb by the charging current Ib.

(Step S34) The charging voltage Vchg exceeds the predetermined level and an upper phase side driving voltage VH is established. The upper phase side driving voltage VH is output from the capacitor Cb by discharging and is applied to the LVIC 11U-1 via the terminal VccU. The internal circuit 11b1 in the LVIC 11U-1 receives the upper phase side driving voltage VH and drives the gate of the U-phase switching element 13a.

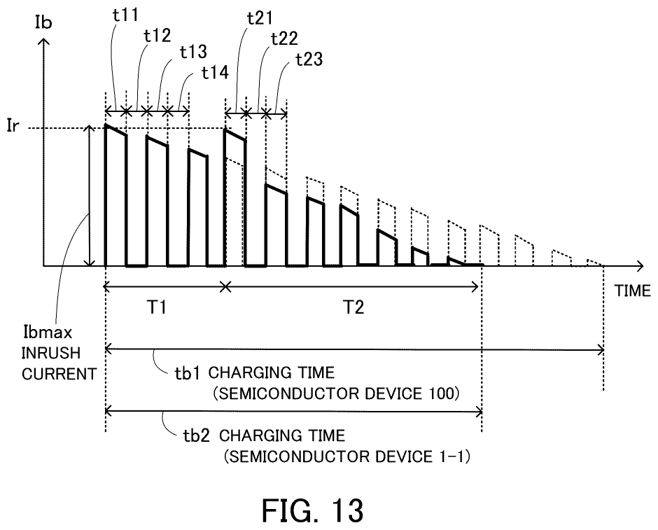

FIG. 13 illustrates an example of the waveform of a charging current at initial charging time. In FIG. 13, a vertical axis indicates the charging current Ib and a horizontal axis indicates time.

(Time zone T1) A voltage level at the terminal VccU (voltage level of the charging voltage Vchg) is lower than the threshold voltage Vth at initial charging beginning time. The switch sw0 is in an off state and the limiting resistor Rb1 is selected.

(Interval t11) When the LVIC 12 receives via the terminal VinX an X-phase driving signal which gives instructions to turn on the X-phase switching element 16a, the LVIC 12 turns on the X-phase switching element 16a.

At this time, electric charges are not stored in the capacitor Cb. That is to say, the capacitor Cb is in a state before being charged. Accordingly, a large inrush current Ibmax flows to the capacitor Cb. However, the inrush current Ibmax flows through the limiting resistor Rb1. A resistance value of the limiting resistor Rb1 is set to a large resistance value so that a peak value of the inrush current Ibmax does not exceed the rated current value Ir. As a result, at initial charging beginning time, the inrush current Ibmax is suppressed so as not to exceed a rated current.

(Interval t12) When the LVIC 12 receives via the terminal VinX an X-phase driving signal which gives instructions to turn off the X-phase switching element 16a, the LVIC 12 turns off the X-phase switching element 16a. Because at this time the other end of the capacitor Cb is not electrically conducted with the negative electrode end of the lower phase power supply VccL, the charging current Ib does not flow.

(Interval t13) When the LVIC 12 receives via the terminal VinX an X-phase driving signal which gives instructions to turn on the X-phase switching element 16a, the LVIC 12 turns on the X-phase switching element 16a. In this case, the charging current Ib flows to the capacitor Cb. However, electric charges are stored in the capacitor Cb during interval t11. Accordingly, a peak value of the charging current Ib flowing to the capacitor Cb during interval t13 is smaller than a peak value of the charging current Ib flowing to the capacitor Cb during interval t11.

(Interval t14) When the LVIC 12 receives via the terminal VinX an X-phase driving signal which gives instructions to turn off the X-phase switching element 16a, the LVIC 12 turns off the X-phase switching element 16a. At this time, the charging current Ib does not flow.

(Time zone T2) Initial charging is begun. After the elapse of predetermined time, a voltage level at the terminal VccU (voltage level of the charging voltage Vchg) becomes higher than or equal to the threshold voltage Vth. The switch sw0 turns on and the parallel combined resistor of the limiting resistors Rb1 and Rb2 is selected.

(Interval t21) When the LVIC 12 receives via the terminal VinX an X-phase driving signal which gives instructions to turn on the X-phase switching element 16a, the LVIC 12 turns on the X-phase switching element 16a.

At this time, the charging current Ib flows through the parallel combined resistor of the limiting resistors Rb1 and Rb2. Because a resistance value of the parallel combined resistor of the limiting resistors Rb1 and Rb2 is smaller than a resistance value of the limiting resistor Rb1, the inrush current Ibmax flows to the capacitor Cb. Though a resistance value of the parallel combined resistor of the limiting resistors Rb1 and Rb2 is smaller than a resistance value of the limiting resistor Rb1, setting is performed so that a peak value of the inrush current Ibmax does not exceed the rated current value Ir. As a result, the inrush current Ibmax is suppressed during interval t21 so as not to exceed the rated current value Ir.

(Interval t22) When the LVIC 12 receives via the terminal VinX an X-phase driving signal which gives instructions to turn off the X-phase switching element 16a, the LVIC 12 turns off the X-phase switching element 16a. Because at this time the positive electrode end of the lower phase power supply VccL is not electrically conducted with the negative electrode end of the lower phase power supply VccL, the charging current Ib does not flow.

(Interval t23) When the LVIC 12 receives via the terminal VinX an X-phase driving signal which gives instructions to turn on the X-phase switching element 16a, the LVIC 12 turns on the X-phase switching element 16a. The charging current Ib flows to the capacitor Cb. However, because electric charges are stored in the capacitor Cb before interval t22, the charging current Ib flowing to the capacitor Cb during interval t23 is smaller than the charging current Ib flowing to the capacitor Cb during interval t21. After that, the same operation is repeated.

During interval t21 in time zone T2, the charging current Ib flows through the parallel combined resistor of the limiting resistors Rb1 and Rb2 having resistance value smaller than a resistance value of the limiting resistor Rb1. As a result, electric charges are stored in the capacitor Cb. Accordingly, the charging current Ib flowing to the capacitor Cb increases.

In time zone T2, the charging current Ib increases. Accordingly, time for which the charging current Ib flows in the semiconductor device 1-1 is shorter than time for which the charging current Ib flows in the semiconductor device 100. That is to say, charging time tb2 for the semiconductor device 1-1 is shorter than charging time tb1 for the semiconductor device 100.

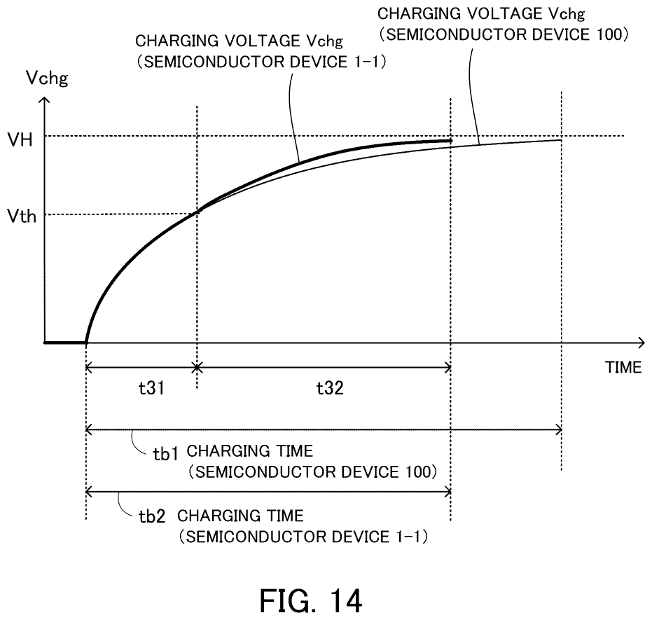

FIG. 14 illustrates an example of the waveform of a charging voltage at initial charging time. In FIG. 14, a vertical axis indicates a charging voltage Vchg and a horizontal axis indicates time.

(Interval t31) The charging voltage Vchg is lower than the threshold voltage Vth and the limiting resistor Rb1 having a large resistance value is selected. The charging current Ib flows to the capacitor Cb and electric charges are gradually stored in the capacitor Cb. As a result, the charging voltage Vchg discharged from the capacitor Cb rises.

(Interval t32) The charging voltage Vchg is higher than or equal to the threshold voltage Vth and the parallel combined resistor of the limiting resistors Rb1 and Rb2 having a small resistance value is selected. The parallel combined resistor of the limiting resistors Rb1 and Rb2 increases the charging current Ib. Accordingly, speed at which the charging voltage Vchg rises in the semiconductor device 1-1 is higher than speed at which the charging voltage Vchg rises in the semiconductor device 100.

With the semiconductor device 1-1, the charging current Ib increases and speed at which the charging voltage Vchg rises is high. Accordingly, time taken for the charging voltage Vchg in the semiconductor device 1-1 to reach the upper phase side driving voltage VH is shorter than time taken for the charging voltage Vchg in the semiconductor device 100 to reach the upper phase side driving voltage VH. That is to say, the charging time tb2 for the semiconductor device 1-1 is shorter than the charging time tb1 for the semiconductor device 100. As illustrated in FIG. 13 and FIG. 14, initial charging in the semiconductor device 1-1 is completed faster in this way than initial charging in the semiconductor device 100 is completed.

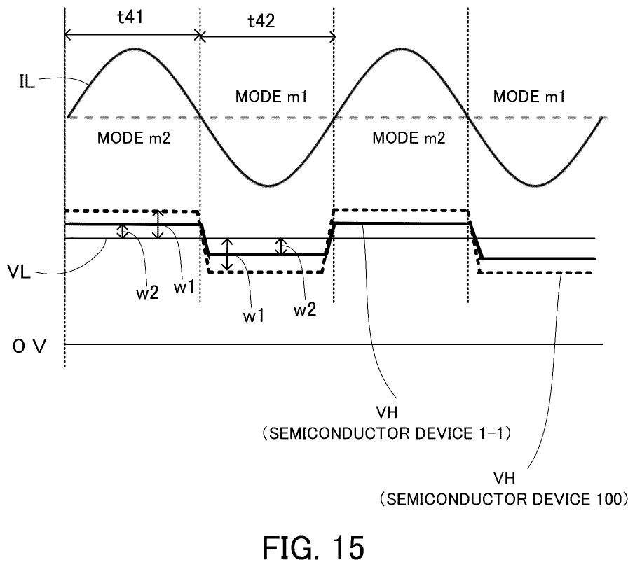

FIG. 15 is a view for describing fluctuations in upper phase side driving voltage at PWM operation time.

(Interval t41) PWM operation is performed in mode m2. A load current IL flows in a positive direction from an output terminal U to a load 3b. In this case, the upper phase side driving voltage VH is higher in a positive direction than the lower phase side driving voltage VL of the lower phase power supply VccL by a fluctuation width w2.

However, at PWM operation time at which the upper phase side driving voltage VH is established, the semiconductor device 1-1 is in an operation state in which the parallel combined resistor of the limiting resistors Rb1 and Rb2 having a small resistance value is selected. Accordingly, the fluctuation width w2 for the semiconductor device 1-1 is smaller than the fluctuation width w1 for the semiconductor device 100.

(Interval t42) PWM operation is performed in mode m1. The load current IL flows in a negative direction from a load 3a to the output terminal U. In this case, the upper phase side driving voltage VH is higher in a negative direction than the lower phase side driving voltage VL of the lower phase power supply VccL by the fluctuation width w2.

However, at PWM operation time at which the upper phase side driving voltage VH is established, the semiconductor device 1-1 is in an operation state in which the parallel combined resistor of the limiting resistors Rb1 and Rb2 having a small resistance value is selected. Accordingly, the fluctuation width w2 for the semiconductor device 1-1 is smaller than the fluctuation width w1 for the semiconductor device 100.

At PWM operation time at which the upper phase side driving voltage VH is established, the semiconductor device 1-1 is in a state in which switching to parallel connection of the limiting resistors Rb1 and Rb2 is performed in this way. Accordingly, fluctuations in the upper phase side driving voltage VH decrease.

As has been described, with the semiconductor device 1-1, if a charging voltage is lower than a threshold voltage, switching to connection of one limiting resistor is performed, a large resistance value is selected, and a charging current is limited. If a charging voltage is higher than or equal to the threshold voltage, switching to parallel connection of two limiting resistors is performed, a small resistance value is selected, and a charging current is limited.

This makes it possible to shorten initial charging time and suppress fluctuations in upper phase side driving voltage at PWM operation time, while suppressing a peak value of an inrush current at initial charging beginning time.

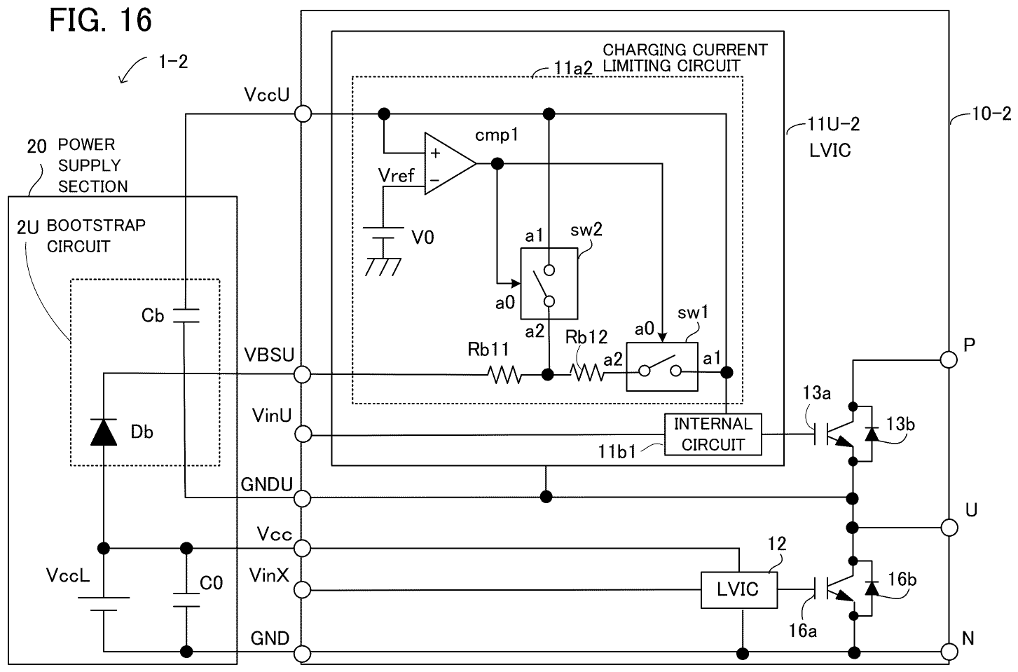

A modification of the semiconductor device according to the embodiment will now be described with reference to FIGS. 16 through 18. With a modification of the semiconductor device according to the embodiment, if a charging voltage is lower than a threshold voltage, switching to series connection of two limiting resistors is performed and a large resistance value is selected. If a charging voltage is higher than or equal to the threshold voltage, switching to connection of one limiting resistor is performed and a small resistance value is selected. The same circuit structure is adopted and the same operation is performed on the U phase, the V phase, and the W phase. Accordingly, the U phase side will be described.

FIG. 16 illustrates a modification of the structure of the semiconductor device according to the embodiment. A semiconductor device 1-2 includes a semiconductor module 10-2 and a power supply section 20. The semiconductor module 10-2 includes an LVIC 11U-2. The other structure of the semiconductor module 10-2 is the same with FIG. 10.

The LVIC 11U-2 includes a charging current limiting circuit 11a2 and an internal circuit 11b1. The charging current limiting circuit 11a2 includes a comparator cmp1, a threshold voltage output source V0, a switch sw1 (first switch), a switch sw2 (second switch), a limiting resistor Rb11 (first limiting resistor), and a limiting resistor Rb12 (second limiting resistor).

The components of the charging current limiting circuit 11a2 are connected in the following way. A non-inverting input terminal (+) of the comparator cmp1 is connected to a terminal VccU, a signal input terminal a1 of the switch sw1, a signal input terminal a1 of the switch sw2, and a power supply voltage supply end of the internal circuit 11b1. An inverting input terminal (−) of the comparator cmp1 is connected to a positive electrode end of the threshold voltage output source V0. A negative electrode end of the threshold voltage output source V0 is connected to a terminal GND.

An output terminal of the comparator cmp1 is connected to a switching control terminal a0 of the switch sw1 and a switching control terminal a0 of the switch sw2. One end of the limiting resistor Rb12 is connected to a signal output terminal a2 of the switch sw1. The other end of the limiting resistor Rb12 is connected to a signal output terminal a2 of the switch sw2 and one end of the limiting resistor Rb11. The other end of the limiting resistor Rb11 is connected to a terminal VBSU.

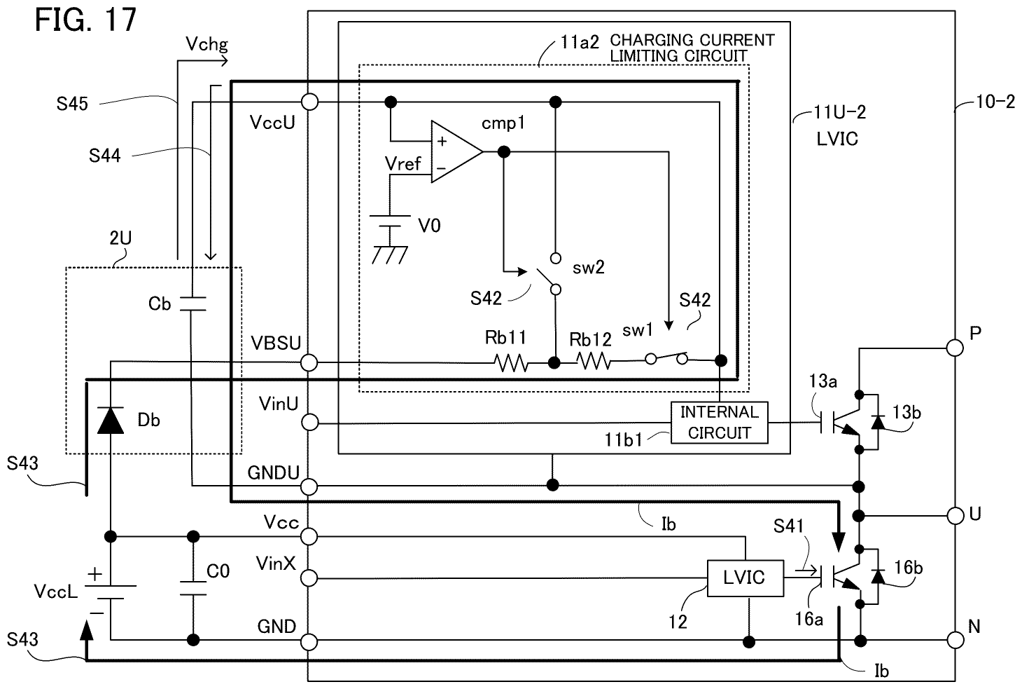

FIG. 17 illustrates an example of the operation of a charging current limiting circuit at initial charging beginning time.

(Step S41) On the basis of an X-phase driving signal input via a terminal VinX, an LVIC 12 turns on an X-phase switching element 16a.

(Step S42) A voltage at a predetermined level is not applied to a terminal VccU at initial charging beginning time. A voltage level at the terminal VccU is lower than a threshold voltage Vth output from the threshold voltage output source V0. At this time, an L-level signal is output from the comparator cmp1. When the switch sw1 receives the L-level signal, the switch sw1 turns on. When the switch sw2 receives the L-level signal, the switch sw2 turns off. In this case, the terminal VccU is connected to the terminal VBSU via a series combined resistor of the limiting resistors Rb11 and Rb12.

(Step S43) One end of a capacitor Cb is electrically conducted with a positive electrode end of a lower phase power supply VccL via the terminal VccU, the series combined resistor of the limiting resistors Rb11 and Rb12, and a diode Db. Furthermore, when the X-phase switching element 16a turns on, the other end of the capacitor Cb is electrically conducted with a negative electrode end of the lower phase power supply VccL via a terminal GNDU and a terminal GND. As a result, a charging current Ib flows.

The charging current Ib flows from the positive electrode end of the lower phase power supply VccL, through an anode of a diode Db, a cathode of the diode Db, the series combined resistor of the limiting resistors Rb11 and Rb12, the terminal VccU, the capacitor Cb, a collector of the X-phase switching element 16a, and an emitter of the X-phase switching element 16a, to the negative electrode end of the lower phase power supply VccL.

When the switch sw1 turns on and the switch sw2 turns off, the charging current Ib flows through the series combined resistor of the limiting resistors Rb11 and Rb12. If an inrush current flows, then a resistance value of the series combined resistor of the limiting resistors Rb11 and Rb12 limits the inrush current so that its peak value does not exceed a rated current value.

(Step S44) Because the charging current Ib flows, electric charges are stored in the capacitor Cb.

(Step S45) Electric charges stored in the capacitor Cb are discharged and a charging voltage Vchg is output from the capacitor Cb by discharging to the terminal VccU.

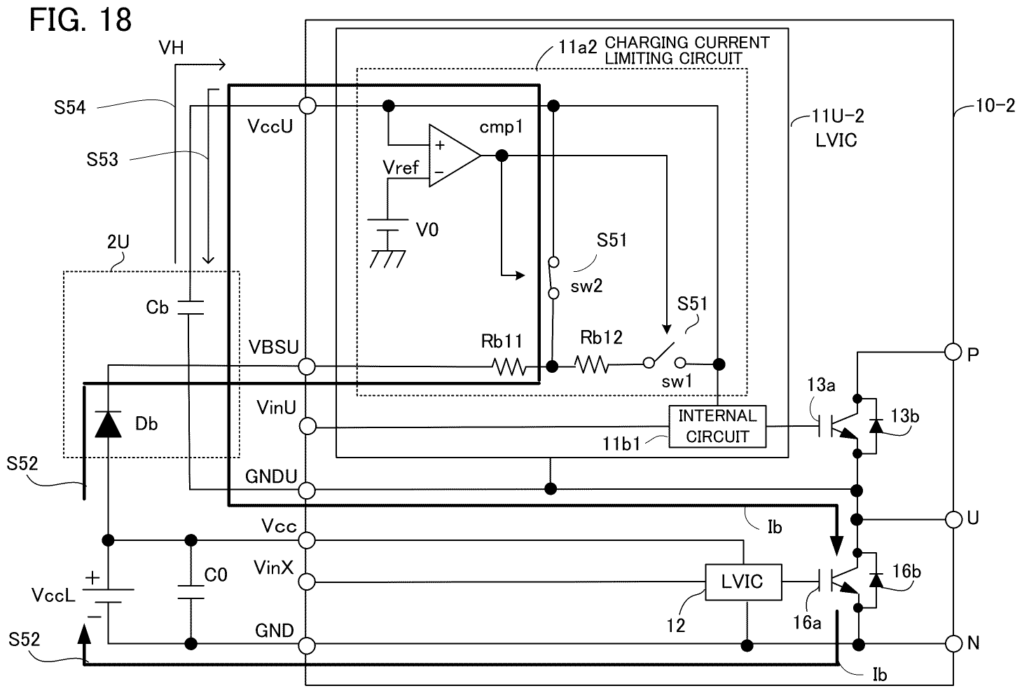

FIG. 18 illustrates an example of the operation of the charging current limiting circuit performed when a charging voltage at initial charging time becomes higher than or equal to a predetermined level.

(Step S51) Initial charging is begun. After the elapse of predetermined time, a voltage level of the charging voltage Vchg rises. A voltage at a predetermined level is applied to the terminal VccU and is higher than or equal to the threshold voltage Vth. At this time, an H-level signal is output from the comparator cmp1. The switch sw1 receives the H-level signal and turns off. The switch sw2 receives the H-level signal and turns on. In this case, the terminal VccU is connected to the terminal VBSU via the limiting resistor Rb11.

(Step S52) The charging current Ib flows from the positive electrode end of the lower phase power supply VccL, through the anode of the diode Db, to the cathode of the diode Db. Furthermore, because the switch sw1 turns off and the switch sw2 turns on, the charging current Ib flows through the limiting resistor Rb11. In addition, the charging current Ib flows from the terminal VccU, through the capacitor Cb, the collector of the X-phase switching element 16a, and the emitter of the X-phase switching element 16a, to the negative electrode end of the lower phase power supply VccL.

When the switch sw1 turns off and the switch sw2 turns on, the charging current Ib flows through the limiting resistor Rb11. If an inrush current flows, then the limiting resistor Rb11 has a resistance value which prevents a peak value of the inrush current from exceeding the rated current value.

(Step S53) Electric charges are stored in the capacitor Cb by the charging current Ib.

(Step S54) The charging voltage Vchg exceeds the predetermined level and an upper phase side driving voltage VH is established. The upper phase side driving voltage VH is output from the capacitor Cb by discharging and is applied to the LVIC 11U-2 via the terminal VccU. The internal circuit 11b1 in the LVIC 11U-2 receives the upper phase side driving voltage VH and drives a gate of a U-phase switching element 13a.

As has been described, with the semiconductor device 1-2, if a charging voltage is lower than a threshold voltage, switching to connection of a series combined resistor of two limiting resistors is performed, a large resistance value is selected, and a charging current is limited. If a charging voltage is higher than or equal to the threshold voltage, switching to connection of one limiting resistor is performed, a small resistance value is selected, and a charging current is limited.

This makes it possible to shorten initial charging time and suppress fluctuations in upper phase side driving voltage at PWM operation time, while suppressing a peak value of an inrush current at initial charging beginning time.

The embodiment has been described. However, the technical scope of the present disclosure is not limited to the description of the above embodiment. Furthermore, it is possible to add various changes or improvements to the above embodiment. In addition, the technical scope of the present disclosure may include an embodiment obtained by adding the changes or improvements and its equivalents without departing from the spirit of the present disclosure.

According to an aspect, an inrush current is suppressed at initial charging time, initial charging time is shortened, and fluctuations in driving voltage are suppressed.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
an upper phase switching element;
a lower phase switching element connected in series with the upper phase switching element;
a lower phase power supply which outputs a lower phase side driving voltage;
a lower phase drive control circuit which receives the lower phase side driving voltage, and drives and controls the lower phase switching element;
a bootstrap circuit which
receives a charging current from the lower phase power supply, responsive to the lower phase switching element being turned on by the lower phase drive control circuit, and
generates a charging voltage therefrom; and
an upper phase drive control circuit
which receives the charging voltage as an upper phase side driving voltage,
which includes a charging current limiting circuit for limiting the charging current flowing from the lower phase power supply to the bootstrap circuit according to a voltage level of the charging voltage,
and
which drives and controls the upper phase switching element.

2. The semiconductor device according to claim 1, wherein the charging current limiting circuit is configured to limit the charging current by
providing a large resistance value when the voltage level of the charging voltage is lower than a predetermined level, and
providing a small resistance value when the voltage level of the charging voltage is higher than or equal to the predetermined level.

3. The semiconductor device according to claim 2, wherein:
the bootstrap circuit includes a diode and a capacitor;
the charging current received by the bootstrap circuit flows through the diode to the charging current limiting circuit;
the capacitor is configured to be charged by the charging current; and
the charging voltage is generated by electric charges stored on the capacitor.

4. The semiconductor device according to claim 3, wherein:
the charging current limiting circuit includes:
a comparator having an inverting input terminal and a non-inverting input terminal, the comparator being configured to output a comparison result by comparing the charging voltage with a threshold voltage at the predetermined level,
a first limiting resistor having a first end and a second end,
a second limiting resistor connected in parallel with the first limiting resistor, the second limiting resistor having a first end and a second end, and
a switch which performs switching according to the comparison result;
the lower phase power supply has a positive electrode end and a negative electrode end, an anode of the diode being connected to the positive electrode end;
the capacitor has:
a first end that is connected to
the non-inverting input terminal of the comparator,
the first end of the first limiting resistor, and
the first end of the second limiting resistor; and
a second end that is connected to the lower phase switching element, so as to be connected to the negative electrode end of the lower phase power supply when the lower phase switching element is turned on;
the threshold voltage is applied to the inverting input terminal of the comparator;
the switch has a signal input terminal and a signal output terminal;
the second end of the first limiting resistor is connected to the signal output terminal of the switch and a cathode of the diode, and the second end of the second limiting resistor is connected to the signal input terminal of the switch;
the switch turns off in response to a low potential level signal being outputted from the comparator, so that the charging current limiting circuit provides the large resistance value that is a resistance of the first limiting resistor; and
the switch turns on in response to a high potential level signal being outputted from the comparator, so that the charging current limiting circuit provides the small resistance value, which is a combined resistance of the first limiting resistor and the second limiting resistor connected in parallel.

5. The semiconductor device according to claim 4, wherein
the charging current flows to generate a first inrush current in response to the switch turning off, and
the first limiting resistor is configured to have a resistance value by which a peak value of the first inrush current is equal to or lower than a rated current value.

6. The semiconductor device according to claim 5, wherein
the charging current flows to generate a second inrush current in response to the switch turning on, and
the first limiting resistor and the second limiting resistor are so configured that the combined resistance keeps a peak value of the second inrush current to be equal to or lower than the rated current value.

7. The semiconductor device according to claim 3, wherein:
the charging current limiting circuit includes:
a comparator having an inverting input terminal and a non-inverting input terminal, the comparator being configured to output a comparison result by comparing the charging voltage with a threshold voltage at the predetermined level,
a first limiting resistor having a first end and a second end,
a second limiting resistor connected in series with the first limiting resistor, the second limiting resistor having a first end and a second end, and
a first switch and a second switch, each of which performs switching according to the comparison result of the comparator, and has a signal input terminal and a signal output terminal;
the lower phase power supply has a positive electrode end and a negative electrode end, an anode of the diode being connected to the positive electrode end;
the capacitor has:
a first end that is connected to
the non-inverting input terminal of the comparator,
the signal input terminal of the first switch, and
the signal input terminal of the second switch; and
a second end that is connected to the lower phase switching element, so as to be connected to the negative electrode end of the lower phase power supply when the lower phase switching element is turned on;
the threshold voltage is applied to the inverting input terminal of the comparator;
the first end of the second limiting resistor is connected to the signal output terminal of the first switch, and the second end of the second limiting resistor is connected to the signal output terminal of the second switch and the first end of the first limiting resistor;
the second end of the first limiting resistor is connected to a cathode of the diode;
the first switch turns on and the second switch turns off, in response to a low potential level signal being outputted from the comparator, so that the charging current limiting circuit provides the large resistance value, which is a combined resistance of the first limiting resistor and the second limiting resistor connected in series; and
the first switch turns off and the second switch turns on, in response to a high potential level signal being outputted from the comparator, so that the charging current limiting circuit provides the small resistance value that is a resistance of the first limiting resistor.

8. The semiconductor device according to claim 7, wherein
the charging current flows to generate a first inrush current, in response to the first switch turning on and the second switch turning off, and
the first limiting resistor and the second limiting resistor are so configured that the combined resistance keeps a peak value of the first inrush current to be equal to or lower than a rated current value.

9. The semiconductor device according to claim 8, wherein
the charging current flows to generate a second inrush current, in response to the first switch turning off and the second switch turning on, and
the first limiting resistor is configured to have a resistance value by which a peak value of the second inrush current is equal to or lower than the rated current value.
